(19) United States
(12) Patent Application Publication
(10) Pub. No.: US 2016/0141199 A1
(43) Pub. Date: May 19, 2016

(54) APPARATUS AND METHOD FOR HOLDING A WORKPIECE

(71) Applicants: Wang Lung TSE, North Point (HK); Hoi Shuen TANG, Kwai Chung (HK); Chun Kit LIU, Tsuen Wan, N.T. (HK)

(72) Inventors: Wang Lung TSE, North Point (HK); Hoi Shuen TANG, Kwai Chung (HK); Chun Kit LIU, Tsuen Wan, N.T. (HK)

(21) Appl. No.: 14/541,363

(22) Filed: Nov. 14, 2014

(51) Int. Cl. H01L 21/683

(52) U.S. Cl. CPC H01L 21/6838

(57) ABSTRACT

The present invention relates to an apparatus for holding a workpiece to allow dicing of the workpiece. The apparatus comprises a base, an inner support member and an outer support member that is more deformable than the inner support member and arranged along a periphery of the inner support member. In use, air is extracted from suction holes of the inner support member, urging the workpiece against the inner and outer support members. Upon such urging, the outer support member deforms to seal a gap between the workpiece and the inner support member. This helps to increase the magnitude of the forces holding the workpiece against the inner support member.

### FIELD OF THE INVENTION

The present invention relates to an apparatus and method for holding a workpiece to allow dicing of the workpiece.

### BACKGROUND OF THE INVENTION

The manufacture of integrated circuits (ICs) commonly involves a process of dicing an IC package strip into individual IC package units. This is usually performed using a jig saw singulation machine.

FIG. 1 shows a perspective view of a typical jig saw singulation machine 100. As shown in FIG. 1, in the jig saw singulation machine 100, a saw jig table 102 is mounted on a chuck station 104, with the chuck station 104 comprising a dicing blade 106 for dicing the IC package strip.

FIGS. 2(a) and (b) show the saw jig table 102 in greater detail. In particular, FIG. 2(a) shows a perspective view of the saw jig table 102 with a part of the chuck station 104 whereas FIG. 2(b) shows a cross-sectional view of the saw jig table 102 with the part of the chuck station 104 along the line AA. The saw jig table 102 is specifically designed according to the size of the IC package strip, and comprises a bottom layer 201 and a top layer 202. The bottom layer 201 is in the form of a rigid base structure made of metal and the top layer 202 is in the form of a support structure made of hard rubber. The chuck station 104 comprises a central cavity 206 and is connectable to a vacuum source. The bottom layer 201 also comprises a cavity 204 whereas the top layer 202 comprises a plurality of suction holes 203. Slots 205 are also included in the top layer 202 to allow the dicing blade 106 to pass through to dice the IC package strip.

To begin the dicing process, a workpiece in the form of an IC package strip is first placed on top of the top layer 202 by a strip loading mechanism. A vacuum source is connected to the chuck station 104 and is switched on to extract air from the central cavity 206 of the chuck station 104. This in turn extracts air from the cavity 204 and the suction holes 203. As a result, pressure inside the suction holes 203 drops below atmospheric pressure. This causes pressure differences between the suction holes 203 and the atmospheric environment, thus inducing forces which urge the workpiece against the top layer 202. These forces hold the workpiece in place, allowing the dicing blade 106 to dice the workpiece as the blade 106 runs through the slots 205.

A problem arises when the workpiece is warped. Strip warpage may occur when there is a mismatch between coefficients of thermal expansion (CTE) of the strip materials including the substrate, the molding compound encapsulation and die materials during the curing process of molding the IC package strip. FIG. 3 shows a situation whereby the workpiece is an IC package strip 300 having large strip warpage. As shown in FIG. 3, the bottom of the warped IC package strip 300 is not flat and thus, a gap is formed between the IC package strip 300 and the top layer 202. This causes leakage flow of air 301 from the atmosphere into the suction holes 203 when the vacuum source is turned on (i.e. during the “chuck vacuum suction” as illustrated in FIG. 3). This in turn results in insufficient pressure differences between the atmospheric environment and the suction holes 203. The forces induced by such insufficient pressure differences are weak and the workpiece cannot be held securely against the saw jig table 102 for dicing.

Prior art methods to address the above-mentioned problem have been developed.

For example, it has been proposed to use a top clamp to flatten and press the IC package strip against the saw jig table. Cutting of the IC package strip while the top clamp presses against the strip is possible as the top clamp includes slots aligned with kerf lines between individual IC package units, so the dicing blade can run through the slots to cut the IC package strip. However, these slots run in only one direction. Therefore, after cutting the strip in the X direction, the top clamp has to be rotated by 90 degrees before cutting in the Y direction can be done. Further, when the top clamp is pressed against the IC package strip, the top view of the strip is blocked. This increases the difficulty in performing vision alignment (e.g. Pattern Recognition (PR) alignment) of cut-lines, and post cutting inspection of kerf position and cutting quality. It is also difficult to apply this prior art method on smaller IC packages (e.g. IC packages of size approximately 2-3 mm).

In another prior art method, a pressing mechanism is added to the strip loading mechanism to flatten the edges of the IC package strip at the time of loading the strip onto the saw jig table. However, to allow the dicing blade to contact the strip for dicing, the strip loading mechanism has to be lifted up from the saw jig table. After this removal of the clamping force, the IC package strip may become warped again if the lift up forces due to the previous warpage is greater than the forces induced by the extraction of air by the vacuum source. Thus, this prior art method does not produce satisfactory results when the warpage of the IC package strip is severe.

### SUMMARY OF THE INVENTION

The present invention aims to provide a new and useful apparatus and method for holding a workpiece to allow dicing of the workpiece.

In general terms, the present invention proposes an apparatus having different levels of deformability at different portions, with the less deformable portions configured to support the workpiece and the more deformable portions configured to deform to seal a gap between the workpiece and the apparatus when the workpiece is urged against the apparatus.

Specifically, a first aspect of the present invention is an apparatus for holding a workpiece to allow dicing of the workpiece, the apparatus comprising: an inner support member comprising suction holes, the inner support member being configured to support the workpiece; a base comprising a cavity connectable to a vacuum source; and an outer support member configured to support the workpiece, the outer support member being more deformable than the inner support member and the vacuum source being operative to extract air from the suction holes via the cavity to urge the workpiece against the inner and outer support members; wherein the outer support member is arranged along a periphery of the inner support member and is configured to deform to seal a gap between the workpiece and the inner support member upon the urging of the workpiece against the inner and outer support members.

By “more deformable”, it is meant that the outer support member is more compliant than the inner support member.

Extracting air from the suction holes causes pressure differences between the suction holes and the atmosphere, in turn inducing forces urging the workpiece against the inner and outer support members. Sealing the gap between the workpiece and the inner support member via the more deformable outer support member can increase the magnitudes of such pressure differences and forces. Thus, the workpiece can be held more securely against the inner support member. Further, since the inner support member is less deformable, the inner support member can provide sufficient support for the workpiece to achieve stable cutting. Therefore, the apparatus according to the first aspect of the invention can provide not only stronger securement of the workpiece against the apparatus, but also stronger support for the workpiece for stable cutting. As compared to the prior art described above, the workpiece can be diced in both the X and Y directions by the apparatus in the first aspect of the invention without having to rotate any top clamp. Further, the workpiece can be viewed during the dicing process and this facilitates vision alignment of cut-lines, and post cutting inspection of kerf position and cutting quality with a vision camera.

The outer support member may be arranged along an entire periphery of the inner support member. This can seal the gap between the workpiece and the inner support member along the entire periphery of the workpiece.

Alternatively, the outer support member may be arranged along only a part of the periphery of the inner support member. For example, the inner support member may be rectangular in shape and the outer support member may be arranged along only two opposite sides of the inner support member. This can help reduce manufacturing costs since less material is required to form the outer support member.

Preferably, the outer support member has a height greater than a height of the inner support member. With this feature, the outer support member can be deformed to a larger extent to form a better seal of the gap between the workpiece and the inner support member when the workpiece is urged against the inner and outer support members. This feature also allows the apparatus to be used for workpieces which are more severely warped as such workpieces are also able to contact and deform the higher outer support member upon urging of the workpieces against the lower inner support member.

Both the inner support member and the outer support member may comprise rubber, with the rubber of the inner support member harder than the rubber of the outer support member. For example, the inner support member may comprise rubber having Shore A hardness of between 50 and 80, and the outer support member may comprise rubber having Shore A hardness of between 10 and 30.

The inner support member and the outer support member may form parts of a unitary member, with the unitary member having varying levels of deformability across its surface. For example, the deformability of the unitary member may increase with a constant gradient from a center of the unitary member to a periphery of the unitary member. This can provide stronger support to the workpiece at the center of the single member and at other areas, the unitary member is sufficiently deformable to seal smaller gaps between the workpiece and the unitary member, and is also sufficiently rigid to provide adequate support to the workpiece at these areas.

A second aspect of the present invention is a method of holding a workpiece to allow dicing of the workpiece, the method comprising: receiving the workpiece with inner and outer support members configured to support the workpiece, wherein the inner support member comprises suction holes; extracting air from the suction holes of the inner support member to urge the workpiece against the inner and outer support members; and deforming the outer support member upon the urging of the workpiece against the inner and outer support members to seal a gap between the workpiece and the inner support member, wherein the outer support member is more deformable than the inner support member and is arranged along a periphery of the inner support member.

### BRIEF DESCRIPTION OF THE FIGURES

An embodiment of the invention will now be illustrated for the sake of example only with reference to the following drawings, in which:

FIG. 1 shows a perspective view of a prior art jig saw singulation machine for dicing an IC package strip;

FIGS. 2(a) and (b) show a saw jig table of the machine of FIG. 1 in greater detail, with FIG. 2(a) showing a perspective view of the saw jig table and FIG. 2(b) showing a cross-sectional view of the saw jig table;

FIG. 3 shows the saw jig table of FIGS. 2(a) and (b) in use with a warped IC package strip;

FIG. 4(a) shows a perspective view of an apparatus for holding a workpiece to allow dicing of the workpiece according to an embodiment of the present invention and

FIG. 4(b) shows a cross-sectional view of the apparatus of FIG. 4(a);

FIG. 5 shows the apparatus of FIGS. 4(a) and 4(b) in use with a warped IC package strip.

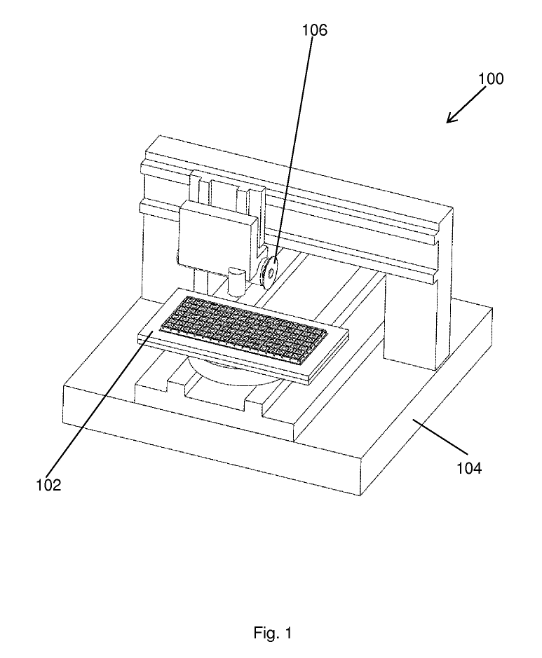

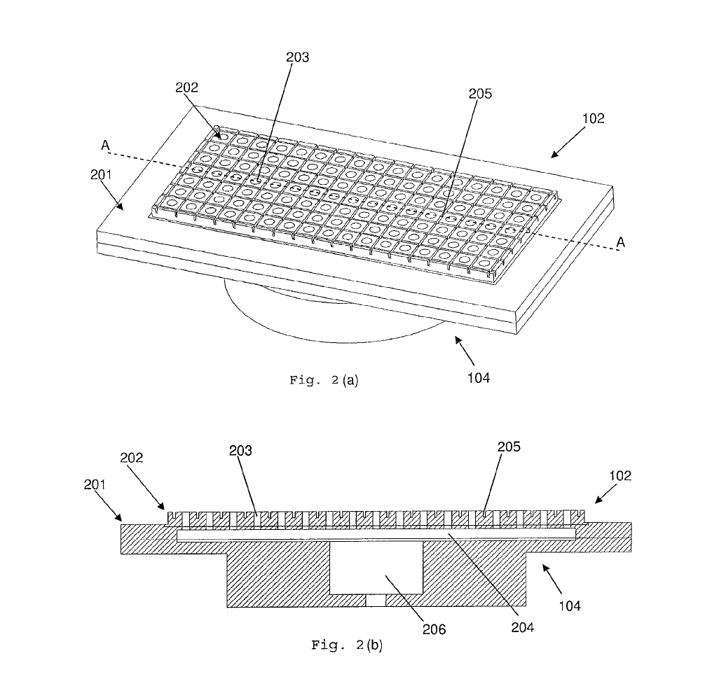

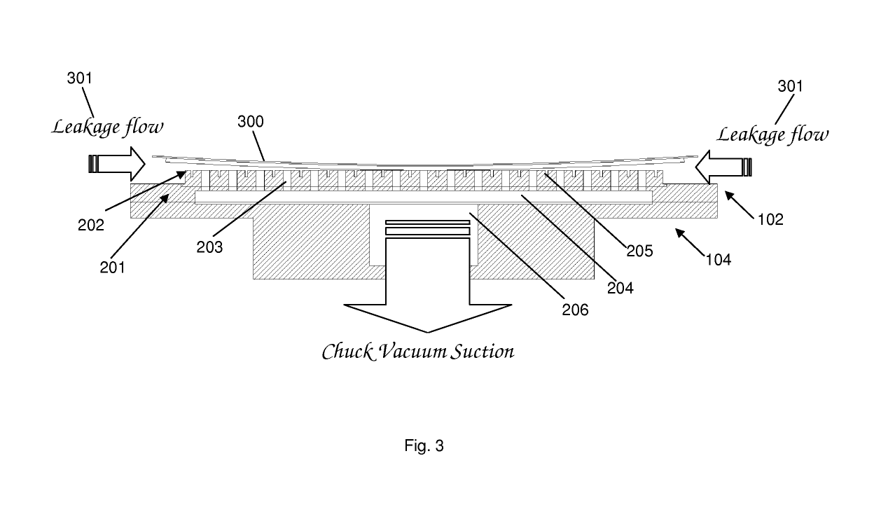

### DETAILED DESCRIPTION OF THE EMBODIMENTS

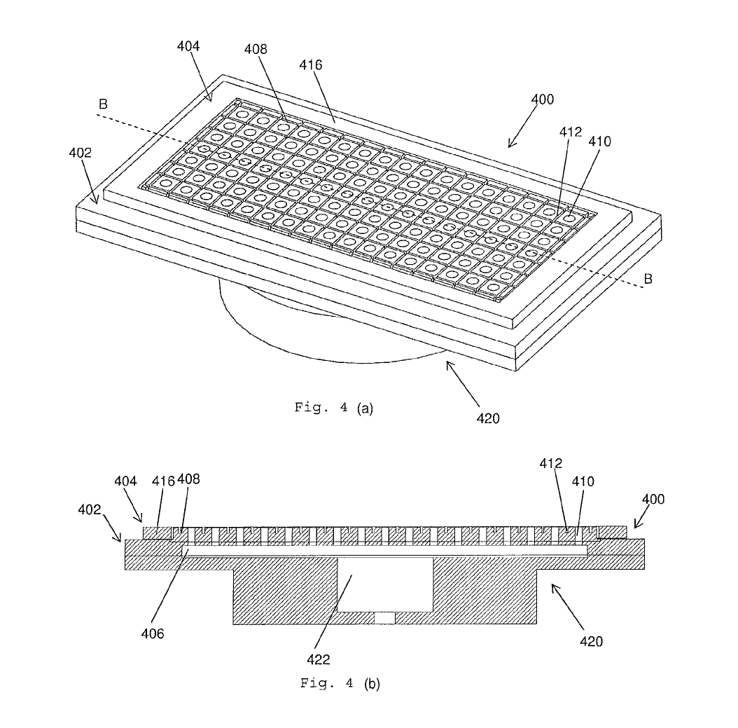

FIG. 4(a) shows a perspective view of an apparatus 400 for holding a workpiece to allow dicing of the workpiece according to an embodiment of the present invention. In FIG. 4(a), the apparatus 400 is shown together with a part of a typical chuck station 420. FIG. 4(b) shows a cross-sectional view of the apparatus 400 with the part of the chuck station 420 along the line B-B. In this embodiment, the workpiece is in the form of an IC package strip.

The apparatus 400 comprises a bottom layer (i.e. base) 402 and a top layer 404.

The bottom layer 402 is formed of metal, and comprises a cavity 406.

The top layer 404 comprises a relatively planar inner support member in the form of a layer of hard rubber 408 having Shore A hardness of between 50 and 80. This layer of hard rubber 408 is configured to support the IC package strip and includes an array of elements, each element having a suction hole 410 and separated from adjacent elements by slots 412. The elements are positioned and sized such that when the IC package strip is placed onto the layer of hard rubber 408, each individual IC package unit of the strip lies over a single element, with the suction hole 410 of the element approximately in the middle of the IC package unit.

The top layer 404 further comprises a relatively planar outer support member in the form of a layer of soft rubber 416 having Shore A hardness of between 10 and 30. The layer of hard rubber 408 is rectangular in shape and the layer of soft rubber 416 forms a rectangular outer rim with a constant width around the entire periphery of the layer of hard rubber 408. Further, the height of the layer of soft rubber 416 is greater than the height of the layer of hard rubber 408.

The chuck station 420 comprises a central cavity 422 connectable to a vacuum source. The suction holes 410 of the top layer 404, the cavity 406 of the bottom layer 402 and the cavity 422 of the chuck station 420 are arranged to be in fluid communication with each other so that when air is extracted from the cavity 422 of the chuck station 420, air is also extracted from the cavity 406 of the bottom layer 402 and from the suction holes 410 of the top layer 404.

In use, a vacuum source is connected to the chuck station 420. An IC package strip is placed onto the layer of hard rubber 408 with each IC package unit positioned above one of the elements. If the IC package strip is warped, a gap exists between the IC package strip and the layer of hard rubber 408. At this point in time, depending on how warped the IC package strip is, the IC package strip may or may not contact the layer of soft rubber 416.

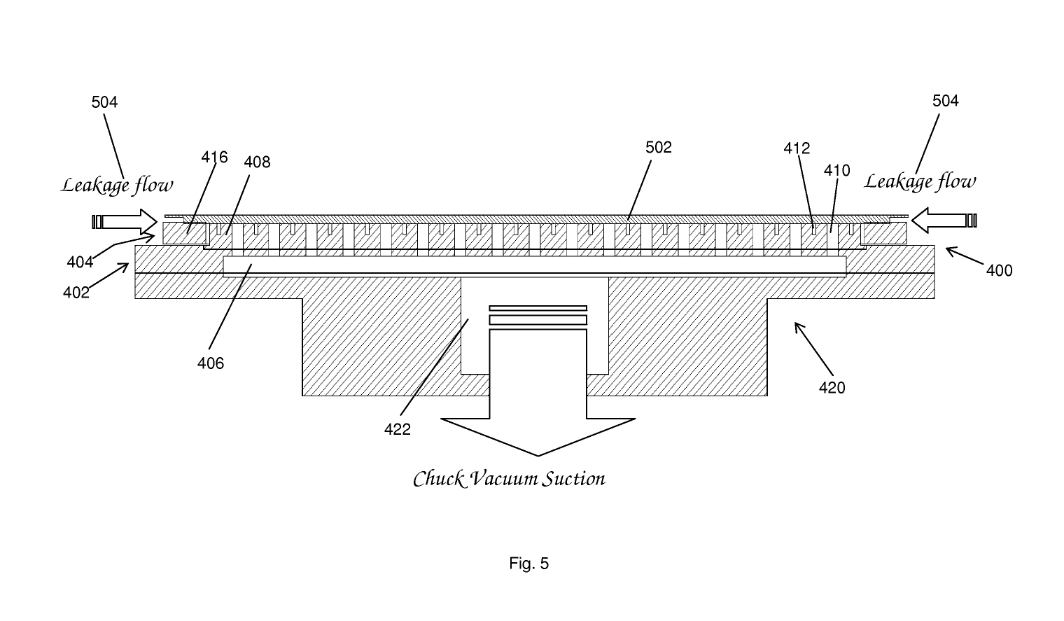

The vacuum source is then turned on. FIG. 5 shows the apparatus 400 in use when the vacuum source is on and when a warped IC package strip 502 is placed on the layer of hard rubber 408. In particular, the vacuum source extracts air from the cavity 422 of the chuck station 420. This causes air to be extracted from the cavity 406 of the bottom layer 402 and in turn, from the suction holes 410 of the top layer 404. Thus, an air path from the suction holes 410 to the cavity 422 via the cavity 406 is formed. This results in pressure differences between the suction holes 410 and the atmospheric environment. Forces are thus induced urging the IC package strip 502 against the layer of hard rubber 408 and the layer of soft rubber 416. In particular, since each IC package unit is positioned above one of the elements of the hard rubber layer 408, each IC package unit is urged against the respective element due to the pressure difference between the suction hole 410 of the element and the atmospheric environment.

Upon the urging of the IC package strip 502 against the layer of hard rubber 408 and the layer of soft rubber 416, the IC package strip 502 presses upon the layer of soft rubber 416. As a result, the layer of soft rubber 416 deforms and seals the gap between the warped IC package strip 502 and the layer of hard rubber 408.

Without the sealing of the gap by the soft rubber layer 416, the induced forces are weak due to air flow leakage 504 from the atmosphere into the suction holes 410 via the gap between the IC package strip 502 and the layer of hard rubber 408. The sealing helps to reduce such air flow leakage 504, thus increasing the pressure differences between the suction holes 410 and the atmospheric environment. The forces induced by these increased pressure differences increase in magnitude accordingly and the IC package strip 502 is urged more securely against the layer of hard rubber 408.

The IC package strip 502 is then diced with the soft rubber layer 416 sealing the gap between the IC package strip 502 and the hard rubber layer 408. At the same time, the IC package strip 502 is well-supported by the hard rubber layer 408 for stable dicing. Thus, good dicing quality can be achieved with the apparatus 400.

Various modifications will be apparent to those skilled in the art.

For example, the inner support member and the outer support member need not have the Shore A hardness as described above. In fact, these members do not even need to be formed of rubber. It is sufficient as long as the inner support member is sufficiently rigid to support the workpiece for stable dicing and the outer support member is more deformable than the inner support member so that the outer support member can deform to seal a gap between a warped workpiece and the inner support member.

Further, the dimensions of the inner support member and the outer support member need not be the same as that in the apparatus 400. However, it is preferred that the outer support member has a height greater than the inner support member. The height of the outer support member may be greater than the height of the inner support member by 0.5 mm to 2 mm, depending on the hardness of the respective members.

The workpiece need not be in the form of an IC package strip. For example, the workpiece can be a circular wafer to be cut. The inner support member and the outer support member need not be rectangular in shape either. These members can take on other shapes and the shape of the members usually depends on the shape of the workpiece to be cut by the apparatus.

The outer support member also need not be arranged along the entire periphery of the inner support member. It can be arranged along only a part of the periphery of the inner support member. For example, if the inner support member is rectangular in shape, the outer support member may be arranged along only two opposite sides (i.e. the lengths or the breadths) of the inner support member. How the outer support member is arranged relative to the inner support member may depend on the manner in which workpieces to be diced by the apparatus are typically warped.

Also, the inner support member and the outer support member may be parts of a single or unitary member having varying levels of deformability across its surface. For example, the center of the single member may be the least deformable to better support the workpiece and the deformability of the single member from the center to the periphery may increase with a constant gradient.

1. An apparatus for holding a workpiece to allow dicing of the workpiece, the apparatus comprising:
an inner support member comprising suction holes, the inner support member being configured to support the workpiece;
a base comprising a cavity connectable to a vacuum source; and
an outer support member configured to support the workpiece, the outer support member being more deformable than the inner support member and the vacuum source being operative to extract air from the suction holes via the cavity to urge the workpiece against the inner and outer support members;
wherein the outer support member is arranged along a periphery of the inner support member and is configured to deform to seal a gap between the workpiece and the inner support member upon the urging of the workpiece against the inner and outer support members.

2. An apparatus according to claim 1, wherein the outer support member is arranged along an entire periphery of the inner support member.

3. An apparatus according to claim 1, wherein the outer support member is arranged along only a part of the periphery of the inner support member.

4. An apparatus according to claim 1, wherein the inner support member is rectangular in shape and the outer support member is arranged along only two opposite sides of the inner support member.

5. An apparatus according to claim 1, wherein the outer support member has a height that is greater than a height of the inner support member.

6. An apparatus according to claim 1, wherein both the inner support member and the outer support member comprise rubber, and wherein the rubber of the inner support member is harder than the rubber of the outer support member.

7. An apparatus according to claim 6, wherein the inner support member comprises rubber having Shore A hardness of between 50 and 80, and the outer support member comprises rubber having Shore A hardness of between 10 and 30.

8. An apparatus according to claim 1, wherein the inner support member and the outer support member form parts of a unitary member, the unitary member having varying levels of deformability across its surface.

9. An apparatus according to claim 8, wherein the deformability of the unitary member increases with a constant gradient from a center of the unitary member to a periphery of the unitary member.

10. A method of holding a workpiece to allow dicing of the workpiece, the method comprising:
receiving the workpiece with inner and outer support members configured to support the workpiece, wherein the inner support member comprises suction holes;
extracting air from the suction holes of the inner support member to urge the workpiece against the inner and outer support members; and
deforming the outer support member upon the urging of the workpiece against the inner and outer support members to seal a gap between the workpiece and the inner support member, wherein the outer support member is more deformable than the inner support member and is arranged along a periphery of the inner support member.
